(19) United States
(12) Patent Application Publication
(10) Pub. No.: US 2002/0102475 A1
(43) Pub. Date: Aug. 1, 2002

(54) Method of curing a photosensitive material using evanescent wave energy

(75) Inventors: Brian Esser, Colchester, VT (US); Dryver R. Huston, S. Burlington, VT (US); Noel V. Pelczarski, Burlington, VT (US); Wolfgang Sauter, Burlington, VT (US)

Correspondence Address: Morgan S. Heller II, Downs Rachlin Martin PLLC, 199 Main Street, P.O. Box 190, Burlington, VT, 05402-0190, US

(73) Assignee: The University of Vermont and State Agricultural College, Burlington, VT

(21) Appl. No.: 10/022,067

(22) Filed: Dec. 18, 2001

Related U.S. Application Data
(60) Provisional application No. 60/256,295, filed on Dec. 18, 2000.

(51) Int. Cl. G03F 7/20; G03F 7/24

(52) U.S. Cl. 430/5; 430/394; 430/321; 430/270.1

(57) ABSTRACT

A method of curing a photosensitive material (10) having a critical electrical field amplitude at which photoinitiation occurs. The method includes contacting the photosensitive material, e.g., a photoinitiator/monomer resin system, with a substrate (18), such as an optical element, so as to form an interface (20) between the photosensitive material and the substrate. A light beam (12) is directed into the substrate such that the light beam is totally internally reflected from the interface within the substrate so that an evanescent wave is created in the photosensitive material. In order for curing to occur, the electric field amplitude of the evanescent wave at the interface must be at least equal to the critical electric field amplitude of the photosensitive material.

### RELATED APPLICATION DATA

This application claims the benefit of priority of U.S. Provisional Patent Application No. 60/256,295, filed Dec. 18, 2000, entitled “Method of Photoinitiating a Chemical Reaction Using Evanescent Waves.”

### FIELD OF THE INVENTION

The present invention relates generally to the field of photochemistry. More particularly, the present invention is directed to a method of curing a photosensitive material using evanescent wave energy.

### BACKGROUND OF THE INVENTION

Thin films are utilized in many aspects of manufacturing and technology. Applications of such films include anti-reflective optical coatings, ultraviolet filters, protective coatings to increase the durability of optical elements, dry lubrication films, abrasion resistant coatings and anti-static coatings, among others. Many of these applications require the thickness of the respective thin films to be precise and/or highly uniform. Present techniques for applying thin films to substrates include physical vapor deposition (PVD), chemical vapor deposition (CVD), spin coating and electrostatic self assembly (ESA). Each of these methods has one or more limitations that restricts its usefulness for certain applications requiring thin films.

PVD typically requires elevating the substrate temperature above 200° C. during the deposition process. Elevating the temperature provides additional energy to the molecules forming the films so as to form a denser film structure. At lower temperatures, however, PVD is generally difficult to control. When the substrate is not heated, or is heated only slightly, low energy molecules form a film through a relatively small number of collisions with the substrate surface or with molecules already trapped on the surface. Very low energy molecules stay mainly at the point of first collision. Films formed in a low temperature PVD process typically have very high porosity and, therefore, are often highly contaminated with vacuum residuals. In addition, lower temperatures cause a relatively high degree of film thickness non-uniformity.

Substrates that cannot be exposed to temperatures higher than about 80° C. require a low temperature deposition process, namely, sputtering. Examples of substrates generally requiring sputtering includes optic fibers, plastics, some polymers and some sensitive glasses and crystals. Unlike unassisted PVD, sputtering can provide low temperature films. However, sputtered films often suffer from increased intrinsic stresses that may deform substrates and result in poor film quality. Sputtering also appears to be limited in terms of film volume when compared to other deposition techniques.

CVD techniques are similar to PVD techniques, but are generally performed at higher temperatures and result in thicker films. This increased thickness, combined with the higher temperatures, limit the applications for which CVD is suitable.

Spin coating techniques are generally limited to flat substrates and applications requiring uniform film thicknesses. In addition, the curing of a spun-coated film is a complex process based upon the coupling of the fluid rheology and solvent evaporation.

ESA is a relatively new process that applies a film to a substrate by alternatingly dipping the substrate into baths containing oppositely charged molecules. ESA, however, does not appear to be compatible with any sort of patterning and is presently in the experimental stage of development.

### SUMMARY OF THE INVENTION

In one aspect, the present invention is directed to a method of initiating a chemical reaction in a photosensitive material having a critical field amplitude. The method comprises the step of contacting the photosensitive material and a first surface of a substrate with one another so as to form an interface between the photosensitive material and the substrate. Then, a light beam is directed into the substrate so as to cause the light beam to be internally reflected within the substrate at said interface such that the light beam creates an evanescent wave within the photosensitive material having a field amplitude at least as great as the critical field amplitude of the photosensitive material.

In another aspect, the present invention is directed to a structure created in part using a light beam. The structure comprises a substrate having a surface and a layer containing a cured photosensitive material. At least a portion of the layer contacts the surface so as to create an interface between the substrate and the layer, the photosensitive material having been cured as a result of the light beam being totally internally reflected within the substrate at the interface.

### BRIEF DESCRIPTION OF THE DRAWINGS

For the purpose of illustrating the invention, the drawings show a form of the invention that is presently preferred. However, it should be understood that the present invention is not limited to the precise arrangements and instrumentalities shown in the drawings, wherein:

FIG. 1 is a cross sectional view of a photosensitive material being photoinitiated using one embodiment of the method of the present invention;

FIG. 2 is a cross-sectional view of a photosensitive material being photoinitiated using another embodiment of the method of the present invention;

FIG. 3 is a cross-sectional view of a photosensitive material being photoinitiated using yet another embodiment of the method of the present invention and

FIG. 4 is a cross-sectional view of a multi-part photosensitive material being photoinitiated using the embodiment of FIG. 1.

### DETAILED DESCRIPTION OF THE INVENTION

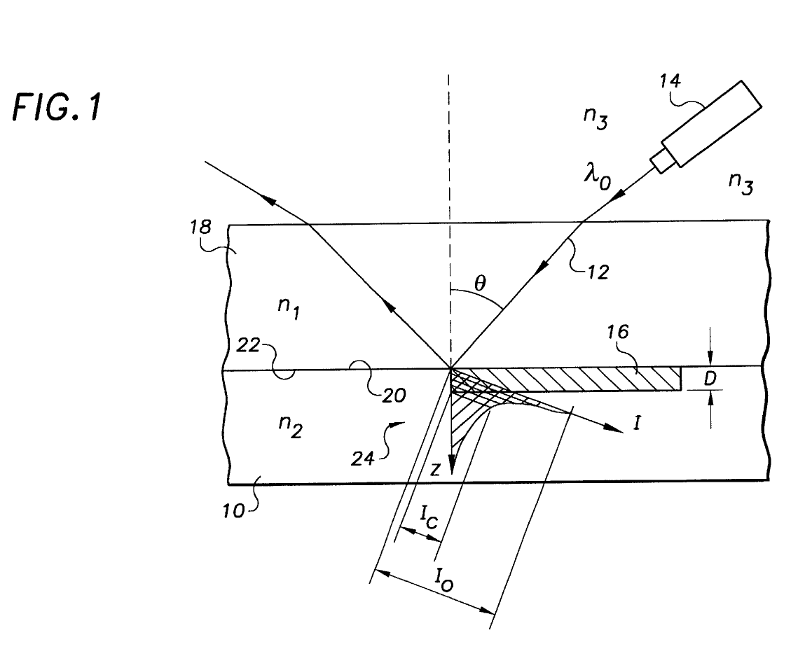

Referring now to the drawings, wherein like numerals indicate like elements, FIG. 1 illustrates in accordance with the present invention a method of photoinitiating a chemical reaction in a photosensitive material 10 using evanescent wave energy from a light beam 11 from a light source 14. Generally, photoinitiation is a term used to describe the initiation of a chemical reaction in photosensitive material 10 by the absorption of light energy having an appropriate wavelength. As described in detail below, the nature of the interaction of evanescent waves and photosensitive material 10 allows the depth D of a photoinitiated region 16 within the photosensitive material to be controlled precisely by adjusting one or more of several parameters.

The method of the present invention may be used, among other things, to create thin films or other structures comprising one or more photoinitiated regions 16 having precisely controlled thicknesses. Such thin films may have a variety of applications in optics as optical coatings, such as anti-reflective coatings, ultraviolet filter coatings, protective coatings to increase the durability of optical elements, dry lubrication coatings, abrasion resistant coatings and anti-static coatings, among others, and in microelectronics manufacturing, such as for the creation of masks, film layers and mirrors, among others. In addition, the method of the present invention may be used to initiate chemical reactions, e.g., surface reactions in various reagents, reactants and/or catalysts alone or in combination with one another.

The phenomena of evanescent waves and their energy are generally well understood. When a light beam, such as light beam 12, travels from one transparent medium, e.g., substrate 18, to another medium, e.g., photosensitive material 10, the light beam is refracted in a manner that depends on the relative indices of refraction of the media and the angle of incidence θ the light beam forms with respect to the interface 20 between the two media, that is located generally at the surface 21 of the substrate 18. If the refractive index, n₁ of substrate 18 is higher than the refractive index n₂ of photosensitive material 10, and if the angle of incidence θ at interface 20 is greater than the corresponding critical angle (sin⁻¹(n₂/n₁), total internal reflection occurs at the interface. When internal reflection occurs, an optical surface wave, known as an evanescent wave, is created and penetrates into photosensitive material 10. The depth that evanescent wave penetrates into photosensitive material 10 is generally confined to within a fraction of a wavelength of light beam incident interface.

As shown by graph 24, the amplitude 1 of the electric field caused by the evanescent wave in photosensitive material 10 decays exponentially with the distance from interface 20 according to the equation:

$$I = {I}_{0} {e}^{\frac{- 4 π z \sqrt{( {n}_{1}^{2} {sin}^{2} θ - {n}_{2}^{2} )}}{{λ}_{0}}} \qquad \{ 1 \}$$

where I₀ is the amplitude of the evanescent electric field at interface 20, z is the distance into photosensitive material 10 from the interface, λ₀ is the wavelength of incident light beam 12, n₁ and n₂ are the indices of refraction of substrate 18 and the photosensitive material, respectively, and θ is the angle of incidence of the light beam. A parameter of interest with respect to photoinitiation is the intensity T of the electric field of the evanescent wave. This intensity is provided by the following equation:

T=|I|² {2}

where I₀ is the amplitude of the electric field as given by equation {1} above. It is this energy that causes photoinitiation to occur.

As shown in FIG. 1, the amplitude I of the electric field is greatest at interface 20 and decays with increasing distance into photosensitive material 10. Photosensitive material 10 typically has associated therewith a critical field amplitude I_{c} below which photoinitiation, e.g., curing, will not occur. Thus, to create a photoinitiated region 16 having thickness D, which is also the depth of the photoinitiated region measured from surface 22 of substrate 18, the electric field amplitude 1 at depth D is equal to critical field amplitude I_{c} of photosensitive material 10. Beyond depth D, the electric field amplitude I is lower than critical field amplitude I_{c}. Thus, photoinitiation does not occur in this region. Since the electric field at depths less than depth D is greater than minimum photoinitiation energy I_{c}, photoinitiation will occur throughout the entire photoinitiated region 16.

Referring to equation {1}, it can be seen that, within certain limits, the depth D at which the intensity of the electric field energy I equal to minimum photoinitiation energy I_{c} and, thus, the thickness of photoinitiated region 16, can be controlled, and/or varied over an area, by changing one or more of the intensity of incident light beam, the angle of incidence of incident light beam, refractive index n₁ of substrate 18, refractive index n₂ of photosensitive material and the wavelength of the incident light. In addition, as mentioned above, the depth that the evanescent wave energy penetrates into photosensitive material 10 is typically on the order of only a fraction of the wavelength λ₀ of incident light beam 12. Therefore, depth D of photoinitiated region 16, and, accordingly, the thickness of a film formed using the present invention, may be very thin, e.g., on the order of 100 nm or less.

When the method of the present invention is used to form thin films by photoinitiating photosensitive material 10, the photosensitive material may be a polymer resin system containing one or more photoinitiators that facilitate curing of the resin within photoinitiated region 16. Photoinitiators can be added to many resins that are cured by either free radical or cationic reactions. Free-radical photoinitiators utilize the absorption of light at the corresponding wavelength to produce primary radicals able to initiate the polymerization of monomers or oligomers. These photoinitiators' mechanisms of action can be photoinduced hydrogen abstraction, electron transfer or cleavage reactions. Cationic photoinitiators generate super-acids, such as protonic or Lewis acids, that catalyze the cationic curing process.

An example of a resin system suitable for use with the present invention as photosensitive material 10 is a yet-to-be-named resin system available from Spectra Group Limited, Maumee, Ohio. This resin system is composed of an acrylate monomer, co-initiators CD 1012 and DIDMA (Sartomer Company, Inc., Exton, Pa.) and photoinitiator H-Nu 635 (Spectra Group Limited). H-Nu 635 is an experimental photoinitiator active in the red region of the visible spectrum. This resin system is blue in its uncured state and becomes transparent after curing. Those skilled in the art will understand that this resin system is but one of many resin systems commercially available from various sources. Depending upon the resin system, light frequencies ranging from ultraviolet to deep red can be used to initiate curing. The variety of resin systems that can be commercially obtained allows the properties and characteristics of the thin films made using the present invention to be tailored to a particular application. In one embodiment, photosensitive material 10 in its un-photoinitiated state may be provided in a pool located beneath substrate 18. In other embodiments, un-photoinitiated photosensitive material 10 may be coated onto surface 22 of substrate 18.

Substrate 18 may be made of any material that is at least partially transparent to the particular wavelength of light beam 12 needed to photoinitiate the chemical reaction in photosensitive material 10. In the context of optical coatings, substrate 18 may be made of any optical grade polymer, such as IPG™ available from Redfern Photonics, Mountain View, Calif., or optical grade glass such as SCHOTT® BK7 glass available from the Schott Corporation, Yonkers, N.Y., and may be any shape that allows light beam 12 to be totally internally reflected at interface 20. Various coatings other than optical coatings, such as low-E coatings for windows, may be applied using the method of the present invention. Thus, substrate 18 may be conventional window grade glass or polymer. Of course, depending upon the type of photosensitive material 10 and its intended application, substrate 18 may be made of another transparent substrate such as quartz or other crystalline material. Although substrate 18 is shown having planar surface 22, surface 22 may be another shape, e.g., curved, such as may occur in various types of optical lenses.

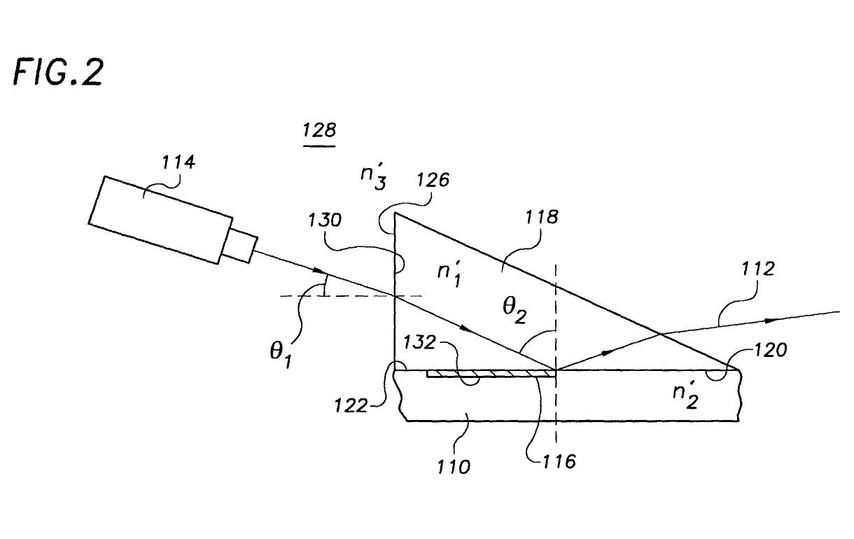

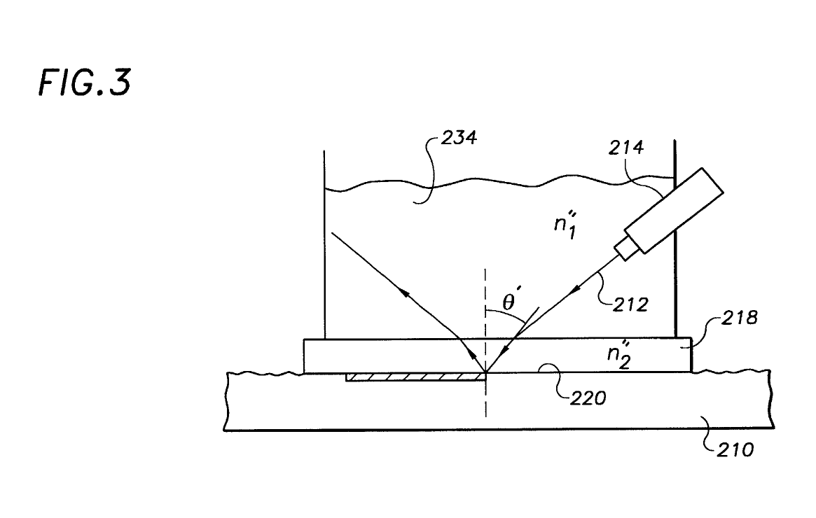

Light source 14 may be a laser that provides light beam 12 having a wavelength commensurate with the type of photosensitive material 10 used. For example, in the acrylate monomer resin system described above, light source 14 may be a red light laser, such as a HeNe laser available from Spectra-Physics, Mountain View, Calif. Light source 14 may be located in air, or other fluid, having a refractive index n₃, that affects the angle of refraction as light beam 12 enters substrate 18. Problems concerning the magnitude of refractive index n₃ relative to refractive index n₁ of substrate 18 are addressed below in connection with FIGS. 2 and 3.

Light beam 12 may be scanned across interface 20 using conventional optical scanning techniques, which are commonly know to those skilled in the art. This allows photoinitiated region 16 to be formed over a larger area than would be created by the light beam striking only a fixed spot. Since conventional scanning techniques allow light beam 12 to be precisely moved relative to interface 20, the present method may also be used to form photoinitiated regions 16 having predetermined patterns (not shown). Similarly, substrate 18 may be moved relative to light beam 12 to create the same effect as scanning the light beam.

FIG. 2 shows an alternative embodiment of the present invention, wherein instead of directing light beam 12 through an upper surface, i.e., a surface spaced from surface 22 and generally parallel to surface 22 of substrate as shown in FIG. 1, light beam 112 may be directed through a side surface 126 of a substrate, such as a triangular prism shaped substrate 118. As used herein and in the claims appended hereto, the term “side surface” indicates a surface of substrate that is not generally parallel to surface 122 at interface 120 between substrate 118 and photosensitive material 110. This includes not only vertical side surface 126, but also various facets (not shown) forming an angle of about 45° to about 90° with respect to surface 122. However, this term would generally not include the opposing optical surfaces of double concave lenses, double convex lenses and convex-concave lenses.

This side-entry method may be desirable, e.g., when refractive index n₁ of substrate 18 is similar to (but greater than) refractive index n₂ of photosensitive material 10, but the refractive index n₃ of the medium containing light source 14, typically air, is much lower than the refractive index n₁ of the substrate. In this situation, the critical angle between substrate 18 (FIG. 1) and photosensitive material 10 becomes so large that achieving total internal reflection using a light beam 12 directed from above the substrate, is difficult, if not impossible, due to the relatively large refraction angle that would occur at the upper surface of the substrate due to the relatively large difference between the refractive index n₃ of the medium containing light source 14 and refractive index n₁ of substrate 18. Those skilled in the art will appreciate that, although substrate 118 of FIG. 2 is shown as being a triangular prism, substrate may be any shape that allows light beam 112 to be internally reflected from interface between the substrate and photosensitive material upon side entry.

In the embodiment of FIG. 2, wherein substrate 118 includes side surface 126 perpendicular to interface 120, as long as light beam 112 is directed at least partially downward toward the interface (but not at an angle greater than the critical angle between medium 128 and substrate 118), the light beam will be refracted toward the interface. The smaller the incidence angle θ₁ formed at the interface 130 between medium 128 and substrate 118, the larger the incidence angle θ₂ formed at the interface between the substrate and photosensitive material. Thus, this side-entry embodiment allows incidence angle θ₂ to be as large as possible.

To illustrate a particular example, substrate 118 was selected to be a triangular prism made of SCHOTT® BK7 glass having a surface accuracy of one wavelength at 632.8 nm and refractive index n₁′ of 1.518. The photosensitive material was the acrylate monomer, discussed above in connection with FIG. 1, having a refractive index n₂′ of 1.475. Thus, the critical angle at the interface 120 between substrate 118 and photosensitive material 110 was sin⁻¹(1.475/1.518)=76.3°. The light source 114 was a Spectra-Physics helium-neon laser, also mentioned above, located in medium 128, which was air having refractive index n₃′ of about 1.0. Although not illustrated, those skilled in the art will understand that various types and/or combinations of mirrors, prisms, waveguides and other structures may be used in conjunction with substrate 118 to achieve the proper angle of incidence θ₂ at interface 120.

Photosensitive material 110 was applied to surface 122 of substrate 118 in a dark environment. Light beam 112 was shone onto interface 120 for approximately 30 seconds, creating photoinitiated, or cured, region 116 of photosensitive material 110. Un-photoinitiated photosensitive material 110, i.e., the photosensitive material outside of photoinitiated region 116, was then removed by swabbing the photosensitive material with an isopropyl alcohol soaked cotton pad (not shown). The uniformity of the free surface 132 of photoinitiated region 116 may be improved by rinsing with a mild alcohol solvent, or other solvent, rather than swabbing with an alcohol soaked pad. One skilled in the art that other photoinitiated materials 116 may be removed with chemicals other than alcohol.

FIG. 3 shows another embodiment of the present invention that may be used to cause total internal reflection at interface 220 between substrate 218 and photosensitive material 210, particularly when the critical angle at the interface is so large that directing light beam 212 from above in, e.g., air or other medium having a refractive index n₃ (FIG. 1) relatively significantly lower than refractive index n₁ of substrate is difficult or impossible. In this embodiment, light source 214 may be directed through an index matching fluid 234, such as an index controllable fluid, e.g., an index matching liquid or gel, having a refractive index n₃ “that relatively closely matching refractive index n₁” of substrate 218. By matching, or nearly matching, refractive index n₃ “of index matching fluid 234 to refractive index n₁” of substrate 218, light beam 212 can pass into the substrate with little or no refraction, and, thus, large angles of incidence θ can be achieved at interface 220 between the substrate 218 and photosensitive material 210. Index matching liquids, such as Cargille 5040 available from Cargille Laboratories, Inc., Cedar Grove, N.J., are commonly available. As will be understood by those skilled in the art, index matching fluid may be contained in any container suitable for a particular application.

Substrate 218 may be made from any suitable at least partially transparent material and may be any shape that allows light beam 212 to be totally internally reflected therein at interface 220. Similarly, photosensitive material 210 may be any material that may be photoinitiated by evanescent wave energy. Example of such materials are discussed above in connection with FIG. 1.

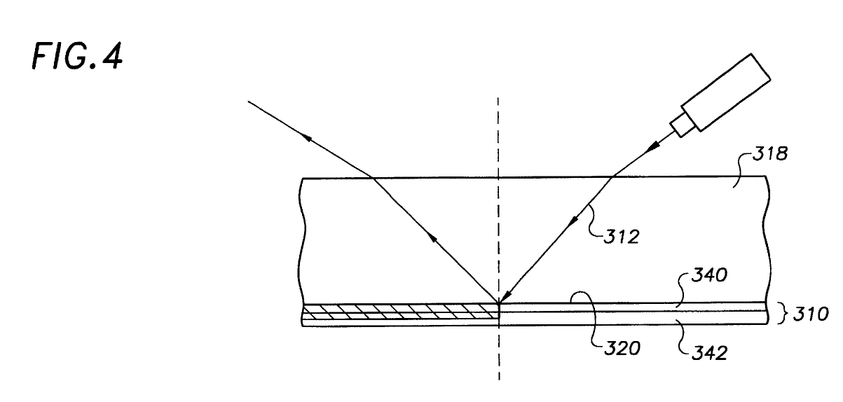

FIG. 4 illustrates the method of the present invention in the context of initiating a chemical reaction in a multi-layer photosensitive material 310. In this embodiment, photosensitive material 310 may comprise one or more materials, such as first material 340 and second material 342, generally forming separate layers prior to photoinitiation. For example, first material 340 may be a reactant, reagent or catalyst applied to surface of substrate, and second material may be a corresponding reactant, reagent or catalyst. When photosensitive material 310 is photoinitiated by the evanescent wave caused by light beam 312, first material 340 and second material 342 react with one another to form a new material at interface 320. First material 340 may be, e.g., a thin layer of potassium ferricyanide, and second material 342 may another material, such as ferric ammonium citrate, contained in another layer, a pool or otherwise be present adjacent the first material. When exposed to light energy, such as evanescent wave energy, these potassium ferricyanide and ferric ammonium citrate iron salts react with one another, oxidizing to their ferric state to form KFeFe[CN]₆, which is Prussian blue in color, and water. This reaction is often used for creating “blue prints” of technical drawings.

While the present invention has been described in connection with several embodiments, it will be understood that it is not so limited. On the contrary, it is intended to cover all alternatives, modifications and equivalents as may be included within the spirit and scope of the invention as defined above.

What is claimed is:

1. A method of initiating a chemical reaction in a photosensitive material having a critical field amplitude, comprising the steps of:
contacting the photosensitive material and a first surface of a substrate with one another so as to form an interface between the photosensitive material and said substrate; and
directing a light beam into said substrate so as to cause said light beam to be internally reflected within said substrate at said interface such that said light beam creates an evanescent wave within said photosensitive material having a field amplitude at least as great as the critical field amplitude of the photosensitive material.

2. A method according to claim 1, wherein the photosensitive material is contained in a pool having a free surface and the step of contacting the photosensitive material and said first surface of said substrate with one another includes contacting said first surface of said substrate with said free surface of said pool.

3. A method according to claim 1, wherein the step of contacting the photosensitive material and said first surface of said substrate with one another includes applying the photosensitive material to said first surface.

4. A method according to claim 1, wherein said substrate has a second surface laterally spaced from said first surface and the step of directing said light beam into said substrate includes directing said light beam through said second surface.

5. A method according to claim 1, wherein said substrate has a lateral side and the step of directing said light beam into said substrate includes directing said light beam through said lateral side.

6. A method according to claim 1, wherein the step of directing said light beam into said substrate includes directing said light beam through an index matching fluid in contact with said substrate.

7. A method according to claim 1, further comprising the step of moving at least one of said light source and said substrate so as to create a predetermined pattern relative to said interface.

8. A method according to claim 1, wherein said substrate is an optical element.

9. A method according to claim 1, wherein the photosensitive material is a precursor to an optical coating.

10. A method according to claim 1, wherein the photosensitive material is a resin system containing at least one photoinitiator.

11. A method according to claim 1, wherein the chemical reaction is curing.

12. A method according to claim 1, wherein said first surface is non-planar.

13. A method according to claim 12, wherein said first surface is curved.

14. A method according to claim 1, wherein the photosensitive material comprises a first portion contacting said surface and a second portion contacting said first portion.

15. A method of varying the depth of photoinitiation in a photosensitive material having a first refractive index, comprising the steps of:
contacting the photosensitive material and a first surface of a substrate with one another so as to form an interface between the photosensitive material and said substrate, said substrate having a second refractive index;
directing a light beam having an intensity and a wavelength into said substrate so that said light beam forms an angle of incidence with respect to said interface; and
changing at least one of:
said intensity of said light beam;
said wavelength of said light beam;
said angle of incidence of said light beam;
the first refractive index of the photosensitive material; and
said second refractive index of said substrate.

16. A method according to claim 15, wherein the photosensitive material is contained in a pool having a free surface and the step of contacting the photosensitive material and said first surface of said substrate with one another includes contacting said first surface of said substrate with said free surface of said pool.

17. A method according to claim 15, wherein the step of contacting the photosensitive material and said first surface of said substrate with one another includes applying the photosensitive material to said first surface.

18. A method according to claim 15, wherein said substrate has a second surface laterally spaced from said first surface and the step of directing said light beam into said substrate includes directing said light beam through said second surface.

19. A method according to claim 15, wherein said substrate has a lateral side and the step of directing said light beam into said substrate includes directing said light beam through said lateral side.

20. A method according to claim 15, wherein the step of directing said light beam into said substrate includes directing said light beam through an index matching fluid in contact with said substrate.

21. A method according to claim 15, further comprising the step of moving at least one of said light source and substrate so as to create a predetermined pattern relative to said interface.

22. A structure created in part using a light beam, comprising:
a substrate having a surface; and
a layer containing a cured photosensitive material, at least a portion of said layer contacting said surface so as to create an interface between said substrate and said layer, said photosensitive material having been cured as a result of the light beam being totally internally reflected within said substrate at said interface.

23. A structure according to claim 22, wherein said substrate is an optical element.

24. A structure according to claim 22, wherein said substrate is made of glass.

25. A structure according to claim 22, wherein said substrate is made of a polymer.

26. A structure according to claim 22, wherein said layer is an optical coating.

27. A structure according to claim 22, wherein said layer comprises a predetermined pattern.

28. A structure according to claim 22, wherein said layer has a thickness that varies in a predetermined manner.

29. A structure according to claim 22, wherein the light beam has a wavelength and said layer has a thickness less than the wavelength of the light beam.

30. A structure according to claim 22, wherein the layer has a thickness of less than 100 nm.

31. A structure created in part using a light beam having a wavelength, comprising:
a substrate having a surface; and
a layer containing a photosensitive material cured by the light beam and having a thickness less than the wavelength of the light.

32. A structure according to claim 31, wherein said thickness varies in a pre-determined manner across said substrate.

33. A system for initiating a chemical reaction using evanescent wave energy having a field amplitude, comprising:
a substrate;
a photosensitive material contacting said substrate so as to form an interface between said substrate and said photosensitive material, said photosensitive material having a critical field amplitude; and
a light source generating a light beam directed into said substrate such that said light beam is totally internally reflected at said interface so that the field amplitude of the evanescent wave from said beam of light at said interface is at least as great as said critical field amplitude of said photosensitive material.

34. A system according to claim 33, wherein said substrate is an optical element.

35. A system according to claim 33, wherein said substrate is made of glass.

36. A system according to claim 33, wherein said substrate is made of a polymer.

37. A system according to claim 33, wherein said photosensitive material is a precursor to an optical coating.

38. A system according to claim 33, wherein said photosensitive material comprises a first portion contacting said surface and a second portion contacting said first portion.
